(19) United States
(12) Patent Application Publication
(10) Pub. No.: US 2025/0378251 A1
(43) Pub. Date: Dec. 11, 2025

(54) Optimized Design Process for High Performance Specialized Machine Learning ASICs

(71) Applicant: Thomas Eric Guttenberger, Dearborn, MI (US)

(72) Inventor: Thomas Eric Guttenberger, Dearborn, MI (US)

(21) Appl. No.: 18/739,361

(22) Filed: Jun. 11, 2024

(51) Int. Cl. G06F 30/34

(52) U.S. Cl. CPC G06F 30/34

(57) ABSTRACT

Disclosed is a design process for high-performance specialized machine learning ASICs, optimized for given models and training or inference hardware end use. Modern Large Language Models (LLMs) and deep learning models can require trillions of parameters to be calculated, and the hardware currently used is not tailored for specific models or input datasets. A key tuneable parameter in custom hardware design is the encoding size of numbers. FPGA prototypes are used to test custom number encoding sizes, which informs the final fabricated design which is created with optimized RTL for the encoding size with attention to number register locations, and component sizes. By first analyzing specific machine learning models on prototype FPGA hardware with variable encoding sizes, the optimal number(s) for encoding size for both training and inference can be identified. By experimentally establishing an optimized encoding sizes for the specific computing use case wasted overhead in terms of physical registers is minimized. The approach herein minimizes research and development costs while optimizing encoding sizes for machine learning ASICS.

### BACKGROUND OF THE INVENTION

### Field of the Invention

The present invention is related to the field of computer processors. More particularly, the invention relates to a process for development for customized high performance machine learning ASICs.

### Background

The advent and popularization of Large Language Models (LLMs) such as GPT4 and other generative AI models has brought these technologies to the forefront of industry and public attention. As these models grow in size and complexity, the efficiency of computing for such models is becoming a critical concern. The development of specialized computer hardware designed to handle the computational workloads associated with machine learning interference and training specifically has been one of the primary responses to this challenge.

One of the key factors influencing the efficiency of computation in large language models is the size and method of encoding numbers. The memory overhead and computation times of machine learning hardware are directly impacted by the manner in which numbers are encoded. By reducing the memory footprint required for encoding numbers, a larger portion of the hardware can be dedicated to performing calculations, thus improving overall efficiency.

In modern deep learning, the impact of the precision of number encodings on model performance is not yet fully understood. Some models and datasets may still function effectively with lower precision encodings, while others may experience performance deterioration. The exact point at which performance begins to degrade will vary depending on the specific problem, dataset, and model in question.

To address this issue, a method herein is proposed that involves conducting prototype experiments to determine degradation thresholds on Field Programmable Gate Array (FPGA) prototypes. By identifying the minimum memory footprint encodings that maintain acceptable accuracy metric performance levels, these encodings can then be incorporated into fabricated finished circuits, resulting in hardware that is optimized for the specific problem type and input characteristics.

In the context of AI edge or cloud computing systems, this approach can be implemented with routing mechanisms for execution requests to different hardware components that are specialized and optimized for the given input characteristics and model type. By doing so, it is possible to improve the overall efficiency and performance of AI computer systems while minimizing resource consumption.

### SUMMARY

The present invention relates to a method and process for optimizing the design of machine learning application-specific integrated circuits (ASICs) through FPGA prototyping, custom toolchain development, and experimental evaluation of different encoding sizes and configurations. The objective is to determine the optimal encoding size for machine learning ASICs, minimizing memory overheads and computation times, while maintaining the performance of the learning algorithms.

The invention includes a method for FPGA prototyping to determine the optimal encoding size for machine learning ASICs (claim 1), as well as a method for developing custom toolchains to facilitate experimentation with different encoding sizes and configurations (claim 2). The invention also encompasses a method for conducting training and inference degradation experiments with generative large language, image, video, sound, informatic, and multimodal models to evaluate the impact of different encoding sizes (claim 3).

Additionally, the invention involves a method for establishing degradation limits for each model and dataset property combination, wherein dataset properties may include statistically quantifiable parameters such as minimum, maximum, standard deviation, skewness, etc. (Claim 4). Based on the experimental results, the invention provides a method for creating final design layouts for machine learning ASICs with optimized Register Transfer Level (RTL), improving upon the initial FPGA prototype (claim 5).

The invention further provides a process for optimizing the design of machine learning ASICs by performing the methods of claims 1 through 5 in sequence (claim 6). Through this process, FPGA prototyping is utilized to determine the optimal encoding size, custom toolchains are developed for experimentation, degradation experiments are conducted, degradation scores are established for model and dataset property combinations, and final design layouts with optimized RTL are created based on experimental results.

By implementing the methods and processes described in the claims, the present invention aims to optimize the design of machine learning ASICs, enabling more efficient and effective execution of large-scale AI models, for applications in edge and cloud computing environments.

### BRIEF DESCRIPTION OF THE DRAWINGS

FIG. 1 illustrates the design process flowchart for optimizing machine learning ASICS.

### DETAILED DESCRIPTION

With all other things being equal, the lower the precision of number encoding in hardware, the more efficient it will be due to several factors. First, lower precision encoding requires less memory and storage, leading to a reduced memory footprint for computations. This reduction in memory usage can result in faster data access times and reduced power consumption. Second, lower precision encoding can lead to faster arithmetic operations, as fewer bits need to be processed for each calculation. This can result in higher throughput and overall system performance. Despite these advantages, typically only standard number sizes such as 16 or 32-bit numbers are used in GPUs, TPUs, and XPUs. FPGAs can be used to prototype different number encoding sizes, but factors such as RTL and resource locations will prevent FPGAs from competing in speed with custom XPUs. The registers and component locations were built to be generic and reprogrammable, and therefore FPGAs will contain inexact amounts of registers dedicated to required components and will not be optimized for the specific requirements.

By prototyping with FPGAs and accompanying toolchains, experiments with lower precision number encodings can be run. The experiments will assess model accuracy metrics for commonly used generative and other AI methods. The accuracy of the outputs will be assessed, and be chosen based on a threshold before significant accuracy loss relative to the advantages of the smaller encoding. In this way, the minimum number encoding is experimentally determined and can inform the final layout design of a custom fabricated ASIC. The size of the number encoding will influence the exact size requirements and locations of chip components, such as ALUs, memory components, etc.

A design process for custom hardware tailored for specific models and use cases which starts by examining accuracy degradation of model results on progressively less precise hardware is claimed. This process is critical to cost effective development of custom fabricated ASIC. Without this process, fabricated hardware number precision is chosen arbitrarily and will result in sub-optimal performance for the given computing task. The other alternative will be a massive amount of research and development waste optimizing RTLs for several different number encoding designs, of which only one size will be optimal for a given problem. With the design process described herein, the optimal encoding size for a given model and dataset input can be designed. In order for the hardware to be competitive with modern XPUs, the FPGA prototype needs to be converted to an RTL optimized layout for that encoding size and custom etched.

### Description of the Drawings

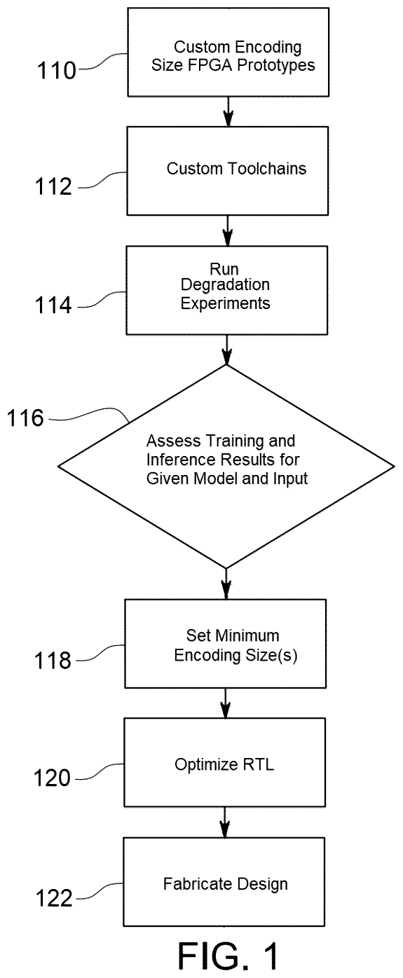

FIG. 1 is a flow chart illustrating the design process of high performance machine learning ASIC. Components of the invention include 110) Custom FPGA Encoding Prototypes, 112) Custom Toolchains, 114) Running Degradation Experiments, 116) Assessment of Results, 118) Set Encoding Size(s) 120) Optimize RTL, and 122) Fabricate the Final Design. These components work together to form the design process described herein. The design process finds the optimal encodings for any given problem and hardware use (training or inference) and then optimizes it performance with respect to layout design.

The invention is a design process which constitutes different components or stages which need to be researched or developed. The first component of the invention, the FPGA Custom Encoding Prototypes (110) can be made using any type of Hardware Description Language. Languages or development kits use to develop this component can include but is not limited to VHDL, Verilog, CatapultC, Matlab HDL coder, C, and SystemC. The second component required to test any custom encoded

Custom Toolchains (112) are software components required to support experimentation with the custom hardware. These toolchains be developed in order to execute the machine learning model software code with the custom FPGA prototype hardware. Some elements of the custom tools chains include a compilers, support libraries and runtime systems, debugging and profiling tools, hardware abstraction layer, integration with machine learning framework and code. The compiler is responsible for translating high-level machine learning model code, written in languages such as Python, C++, or other widely-used programming languages. The compiler may incorporate domain-specific optimizations, such as loop unrolling, dataflow analysis, or memory hierarchy optimizations, to improve the performance and efficiency of the generated code. Custom libraries and runtime systems provide a set of pre-built functions, data structures, and application programming interfaces (APIs) tailored to the needs of machine learning models running on custom hardware. Custom debugger and profiling tools are essential for identifying and resolving issues in the machine learning model code and the custom hardware and abstraction layers necessary. Integrating executable machine learning models running on frameworks such as TensorFlow, PyTorch, or Caffe to execute the code. These integrations will allow for different software implementations of the models to be built onto the hardware.

The third step in the process is to run experiments to test for degradation (114) of output from popular models. The step of creating and running experiments can be done by setting a machine learning task for a particular model, and test a range of prototypes with different encoding precision settings. The tests should measure Type 1 and Type 2 errors, and the minimum precision encoding without any loss in performance measure should be selected for that given model, task, and input set type. Experiments involve administering tests to generative or classification models. The models and datasets accounted for in the testing process should span different machine learning problem domains such as natural language processing, multiomics research, image processing, video processing, and audio processing. Assessment of the results (116) involves examination of model outputs and determination in degradation thresholds. Hypothesis testing should be conducted to examine the differences in results from different number encoding precision levels, A sufficient number of samples should be used to assess the results and the effectiveness measures should reach a steady state estimate.

Based on the assessment of the experiment results, setting encoding precision levels (118) can be informed by single model for specialized development for only that application, or it can be chosen based on a aggregate outcome of a larger set of models. In the experimentation process, it is expected that different problem domains and model architectures will have different requirements in precision.

The next step in the process after the encoding size has been set is to optimize the RTL (120). Optimizing RTL for a custom fabricated chip with a custom-sized number encoding involves modifying and refining the RTL description to achieve better performance, lower power consumption, and smaller area. Steps and components include a) Arithmetic Logic Units to perform arithmetic operations efficiently, b) memory and storage design to support the custom-sized number encoding. Memory and storage design involves creating custom-sized registers, caches, and memory banks that can store and retrieve the custom-sized numbers efficiently, c) data path and control path to support the custom-sized number encoding, d) custom libraries and core that support the custom-sized number encoding, e) power and clock management to efficiently handle the custom-sized number encoding. This includes designing custom-sized clock dividers, power gating, and dynamic voltage and frequency scaling techniques that can save power while maintaining performance, f) EDA tool customization such as logic synthesis, place and route, and timing analysis, to support the custom-sized number encoding, and g) verification and validation of the custom RTL design with the custom-sized number encoding.

Finally once a once a validated RTL design is completed, the ASIC is ready for fabrication (122). The finalized design can be converted into a set of photomasks or reticles used in the lithography process. These masks can contain the patterns for each layer of the chip, and they are used to transfer the design onto the silicon wafer. High-quality silicon wafers can be prepared by slicing them from a single crystal ingot, followed by polishing and cleaning to create a smooth, defect-free surface for subsequent processing steps. The photomasks can be used to transfer the chip design onto the silicon wafer through a process called photolithography. Ultravioletlight is projected through the mask onto a photosensitive material applied on the wafer, creating a pattern that matches the chip design. Advanced lithography techniques, such as extreme ultraviolet lithography where the final chip is fabricated with optimized conditions for functionality and yield.

### How to Use the Invention

The design process invention is used to produce hardware for optimized calculation hardware for specific machine learning problems. The process described herein optimizes the costs associated with producing custom number encoding machine learning ASICs. The ASICs produced as a result of the process can be used with a standard or customized cloud or edge computer systems. A plurality of hardware devices can be used in a single computer system.

### Embodiments

An alternative embodiment of the invention is where the FPGA and Custom Toolchain components are replaced with simulation software designed to mimic the number encodings. This simulation software would need to be applied correctly to round intermediates of calculations, namely the multiplication products, in order to accurately represent the usage of the number encoding at the lowest hardware level. The purpose of either the simulation software or the custom FPGAs with custom toolchains is to execute machine learning training or inference tasks using numbers of given precision encodings. Quantization of numbers at the lowest level is clearly feasible to do when using FPGAs and custom toolchains as claimed, whereas a software simulation to stand in this place may or may not be a feasible alternative embodiment. The rest of the design process including experimentation and optimization as a whole remains the same with this component interchanged.

1. A method for FPGA prototyping to determine the optimal encoding size at the lowest level for machine learning ASICs.

2. A method for developing custom toolchains to facilitate experimentation with different encoding sizes and configurations.

3. A method for conducting training and inference degradation experiments with learning algorithms, such as GPT-4 or LLAMA among others, to evaluate the impact of different encoding sizes.

4. A method for establishing degradation scores for each model and dataset property combination, where a dataset property may include statistically quantifiable parameters such as minimum, maximum, standard deviation, skewness, etc.

5. A method for creating final design layouts for machine learning ASICs with optimized RTL (Register Transfer Level) based on the experimental results, improving upon the initial FPGA prototype by: a. Utilizing the reprogrammable advantage of FPGAs, while minimizing the cost and unused physical space on the chips; b. Optimizing the physical location of components in EDA layout design using tools such as Cadence, or Synopsys, or equivalent software to place complementary units in close proximity; c. Ensuring that supporting number caches and registers, such as memory and caches, are designed to accommodate the exact encoding sizes determined by the experimentation process.

6. A process for optimizing the design of machine learning ASICs by performing the methods of claims 1 through 5 in sequence, wherein FPGA prototyping is used to determine the optimal encoding size, custom toolchains are developed for experimentation, degradation experiments are conducted, degradation scores are established for model and dataset property combinations, and final design layouts with optimized RTL are created based on experimental results.
